(19) United States
(12) Patent Application Publication
(10) Pub. No.: US 2012/0190210 A1
(43) Pub. Date: Jul. 26, 2012

(54) SILICON ETCHING SOLUTION AND ETCHING METHOD

(75) Inventors: Yoshiko Fujioto, Tokyo (JP); Ryuji Sotoaka, Tokyo (JP)

(73) Assignee: MITSUBISHI GAS CHEMICAL COMPANY, INC., Tokyo (JP)

(21) Appl. No.: 13/499,131

(22) PCT Filed: Sep. 29, 2010
(86) PCT No.: PCT/JP2010/066978

§ 371 Date: Mar. 29, 2012

(30) Foreign Application Priority Data
Oct. 2, 2009 (JP) 2009-230477

(51) Int. Cl. H01L 21/302; C09K 13/00; C09K 13/02

(52) U.S. Cl. 438/753; 252/79.5; 252/79.1; 257/E21.214

(57) ABSTRACT

Provided are an etching solution in which in etching processing of silicon, particularly in anisotropic etching processing of silicon in a manufacturing process of semiconductors or MEMS parts, a high etching rate is realized by suppressing a lowering an Si etching rate, which is characteristic in a hydroxylamine-containing etching solution and is caused when Cu exists in the solution, and an etching method. The etching solution is a silicon etching solution which is an alkaline aqueous solution containing an alkaline hydroxide, hydroxylamine, and a thiourea and is characterized by dissolving anisotropically monocrystalline silicon therein, and the etching method is an etching method of silicon using the etching solution.

### TECHNICAL FIELD

The present invention relates to etching processing of silicon, and in particular, the present invention relates to a silicon etching solution which is used for manufacture of MEMS parts or semiconductor devices and to a silicon etching method.

### BACKGROUND ART

In general, in the case of etching a silicon single crystal substrate with a chemical solution, a method of performing etching with an acid based etching solution that is a mixed aqueous solution in which components such as hydrofluoric acid and nitric acid, are added, or a method of performing etching with an alkali based etching solution that is an aqueous solution of potassium hydroxide (KOH), tetramethylammonium hydroxide (hereinafter also expressed simply as “TMAH”), or the like is carried out (see Non-Patent Documents 1 and 2).

In the case of using an acid based etching solution, the etching proceeds in view of the fact that a silicon surface is oxidized with a component having an oxidation action, such as nitric acid, to produce silicon oxide, and this silicon oxide is dissolved as silicon fluoride by hydrofluoric acid or the like. A characteristic feature to be brought in performing etching with an acid based etching solution resides in the matter that the etching proceeds isotropically. An etching rate of the acidic etching solution varies depending upon a mixing ratio of hydrofluoric acid and nitric acid and is from about 1 to 100 μm/min. But, the acidic etching solution involves such a drawback that it corrodes metal wirings of Cu, Al, or the like, so that it is hardly useful in a process in which a metal coexists.

On the other hand, in the case of using an alkali based etching solution, silicon is dissolved as a silicic acid ion by a hydroxy anion in the solution, and on that occasion, water is consumed to generate hydrogen. When etching with an alkali based etching solution is performed, different from the acid based etching solution, etching in monocrystalline silicon proceeds while having anisotropy. This is based on the fact that there is a difference in a dissolution rate of silicon in every orientation of crystal face of silicon and is also called crystal anisotropic etching. Even in a polycrystal, etching proceeds while keeping anisotropy on microscopic observations. However, in view of the fact that the face orientation of crystal grains is randomly distributed, isotropic etching appears to proceed on macroscopic observations. In amorphous silicon, etching proceeds isotropically on both of microscopic observations and macroscopic observations.

In addition to the aqueous solution of KOH or TMAH, an aqueous solution of sodium hydroxide (NaOH), ammonia, hydrazine, or the like is used as the alkali based etching solution. In etching processing of a monocrystalline silicon substrate using such an aqueous solution, in many cases, a long processing time of from several hours to several ten hours is required, an aspect of which, however, varies depending upon a desired processing shape or a temperature condition for performing the treatment or the like.

For the purpose of shortening this processing time even a little, chemical solutions exhibiting a high etching rate are developed. For example, Patent Document 1 discloses a technology of using, as an etching solution, an aqueous solution having a hydroxylamine added to TMAH. Also, Patent Document 2 discloses a technology of using, as an etching solution, an aqueous solution having a specified compound such as iron, iron(III) chloride, or iron(II) hydroxide added to TMAH and discloses that so far as a degree of the effect for making the etching rate fast is concerned, a combined use of iron and a hydroxylamine is especially suitable. Also, Patent Document 3 discloses a technology of using, as an etching solution, an aqueous solution having a hydroxylamine added to KOH. Also, Patent Document 4 discloses an etching solution composed of an alkali-reducible compound and an anticorrosive (e.g., sugars, sugar alcohols, catechol, etc.). In comparison with a hydroxylamine-free alkaline etching solution, though the hydroxylamine-containing alkaline etching solution as disclosed in Patent Document 1 has such an advantage that the etching rate is greatly enhanced, it involves such a drawback that when the etching solution is heated over a long period of time, the hydroxylamine is decomposed, leading to a lowering of the etching rate.

In order to solve this, Patent Document 5 discloses a technology of adding an acid to an alkali to suppress the decomposition of the hydroxylamine, thereby suppressing the lowering of the etching rate. Also, Patent Document 6 discloses a technology of adding an alkaline salt to the alkali and hydroxylamine to suppress the decomposition of the hydroxylamine, thereby suppressing the lowering of the etching rate. As a patent including KOH, hydroxylamine, and urea, there is exemplified Patent Document 7; however, this patent is a patent related to the development of a photoresist and does not provide any description regarding a silicon etching solution and an etching method.

Also, it is known that in etching of Si {110}, when Cu exists, the etching rate is greatly lowered (Non-Patent Document 3).

Patent Document 1: JP-A-2006-054363

Patent Document 2: JP-A-2006-186329

Patent Document 3: JP-A-2006-351813

Patent Document 4: JP-A-2007-214456

Patent Document 5: JP-A-2009-117504

Patent Document 6: JP-A-2009-123798

Patent Document 7: JP-A-2000-516355

Non-Patent Document 1: Sato, “Silicon Etching Technologies” in Journal of the Surface Finishing Society of Japan, Vol. 51, No. 8, 2000, pages 754 to 759

Non-Patent Document 2: Esashi, 2003 MEMS Technology Outlook, pages 109 to 114

Non-Patent Document 3: Tanaka, Abe, Yoneyama, and Inoue, “Silicon Wet Anisotropic Etching by Controlling the Ppb-level of Impurities in the Solution” in Denso Technical Review, Vol. 5, No. 1, 2000, pages 56 to 61

### DISCLOSURE OF THE INVENTION

### Problems to be Solved by the Invention

In a manufacturing process of semiconductor devices or MEMS parts, there maybe the case where Cu is used as a material to be used for a variety of members inclusive of wirings. Though a hydroxylamine-incorporated alkali based etching solution has such an advantage that an etching rate of silicon is high, it involves such a drawback that when Cu exists on a substrate to be immersed in the etching solution, the etching rate of silicon is conspicuously lowered. Cu causes a lowering of the etching rate even in the case where it exists on the same substrate together with silicon, or even in the case where it exists on other substrate to be immersed simultaneously.

In view of the foregoing problems, an object of the present invention is to provide an etching agent composition which, even in the case where Cu exists on a substrate, is able to keep an etching rate high in silicon etching. A further object of the present invention is to provide an electronic appliance having a silicon substrate processed by this etching method.

### Means for Solving the Problems

In order to solve the foregoing problems, the present inventors made extensive and intensive investigations. As a result, it has been found that even when Cu exists, an alkali based etching agent composition having a composition in which a thiourea is added to a hydroxylamine-containing alkali based etching solution does not cause a lowering of an etching rate of silicon, leading to accomplishment of the present invention. That is, the present invention relates to a silicon etching solution and an etching method and is as follows.
1. A silicon etching solution for dissolving monocrystalline silicon anisotropically, comprising an alkaline aqueous solution containing (1) one or more kinds of alkaline hydroxides selected from potassium hydroxide, sodium hydroxide, and tetramethylammonium hydroxide, (2) hydroxylamine, and (3) a thiourea.
2. The silicon etching solution as set forth above in the item 1, wherein the thiourea (3) is one or more kinds selected from thiourea, N-methylthiourea, 1-allyl-3-(2-hydroxyethyl)-2-thiourea, thiourea dioxide, 1,3-dimethylthiourea, 1-benzoyl-2-thiourea, isopropylthiourea, 1-phenyl-2-thiourea, 1,3-diethylthiourea, diphenylthiourea, benzylthiourea, N-t-butyl-N′-isopropylthiourea, N,N′-diisopropylthiourea, and di-n-butylthiourea.
3. The silicon etching solution as set forth above in the item 1, wherein the thiourea (3) is one or more kinds selected from thiourea, N-methylthiourea, 1-allyl-3-(2-hydroxyethyl)-2-thiourea, thiourea dioxide, 1,3-dimethylthiourea, 1-benzoyl-2-thiourea, isopropylthiourea, 1-phenyl-2-thiourea, 1,3-diethylthiourea, and diphenylthiourea.
4. The silicon etching solution as set forth above in the item 1, wherein the thiourea (3) is one or more kinds selected from thiourea, N-methylthiourea, 1-allyl-3-(2-hydroxyethyl)-2-thiourea, and thiourea dioxide.
5. The silicon etching solution as set forth above in any one of the item 1 to 4, which is used for etching of an object in which a silicon substrate is used, and Cu is used for a constituent member thereof.
6. A silicon etching method for dissolving monocrystalline silicon anisotropically, comprising etching an etching object with an alkaline aqueous solution containing (1) an alkaline hydroxide, (2) hydroxylamine, and (3) a thiourea.
7. The silicon etching method as set forth above in the item 6, wherein the alkaline hydroxide (1) is one or more kinds selected from potassium hydroxide, sodium hydroxide, and tetramethylammonium hydroxide; and the thiourea (3) is one or more kinds selected from thiourea, N-methylthiourea, 1-allyl-3-(2-hydroxyethyl)-2-thiourea, thiourea dioxide, 1,3-dimethylthiourea, 1-benzoyl-2-thiourea, isopropylthiourea, 1-phenyl-2-thiourea, 1,3-diethylthiourea, diphenylthiourea, benzylthiourea, N-t-butyl-N′-isopropylthiourea, N,N′-diisopropylthiourea, and di-n-butylthiourea.
8. The silicon etching method as set forth above in the item 6 or 7, wherein the etching object is one in which a silicon substrate is used, and Cu is used for a constituent member thereof.

### Effect of the Invention

According to the invention of the present application, in silicon etching, even in the case where Cu exists in the solution, a high silicon etching rate which is an advantage of a hydroxylamine-containing alkaline aqueous solution can be realized similar to the case where Cu does not exist.

### BEST MODES FOR CARRYING OUT THE INVENTION

The alkaline hydroxide (1) which is used in the present invention is preferably potassium hydroxide (KOH), sodium hydroxide (NaOH), or tetramethylammonium hydroxide (TMAH), and especially preferably potassium hydroxide or tetramethylammonium hydroxide. Also, as for the alkaline hydroxide (1), these may be used singly or in combination of plural kinds thereof.

Though a concentration of the alkaline compound which is used in the present invention may be a conventional alkaline compound concentration at which a desired etching characteristic is obtained, it is also possible to properly determine the concentration depending upon a solubility of the alkaline compound in water and a concentration of the hydroxylamine and a concentration of the thiourea in the etching agent composition. The alkaline compound is used at a concentration of preferably in the range of from 0.1 to 65% by mass, more preferably in the range of from 1 to 45% by mass, still more preferably in the range of from 5 to 40% by mass, and especially preferably in the range of from 5 to 30% by mass. When the concentration is 0.1% by mass or more, the matter that the silicon etching rate is very slow, or the etching is not achieved is not caused, whereas when the concentration is not more than 65% by mass, deposition or solidification of a crystal in the etching agent composition does not occur, and hence, such is preferable.

A concentration of the thiourea which is used in the present invention is preferably from 1 to 10,000 ppm, more preferably from 1 to 5,000 ppm, still more preferably from 1 to 1,500 ppm, and especially preferably from 5 to 1,200 ppm. When the concentration is 1 ppm or more, a Cu dissolution suppressing effect due to the addition of the thiourea is distinctly obtained, and a lowering of the etching rate of silicon at the time of coexistence of Cu due to the addition of the thiourea can be suppressed. Also, when the concentration is not more than 10,000 ppm, since the concentration does not become close to a saturated concentration of the thiourea, deposition of the thiourea by evaporation of water or the like does not occur.

Among thioureas, thiourea, N-methylthiourea, 1-allyl-3-(2-hydroxyethyl)-2-thiourea, thiourea dioxide, 1,3-dimethylthiourea, 1-benzoyl-2-thiourea, isopropylthiourea, 1-phenyl-2-thiourea, 1,3-diethylthiourea, diphenyl thiourea, benzylthiourea, N-t-butyl-N′-isopropylthiourea, diisopropylthiourea, and di-n-butylthiourea are preferable; thiourea, N-methylthiourea, 1-allyl-3-(2-hydroxyethyl)-2-thiourea, thiourea dioxide, 1,3-dimethylthiourea, 1-benzoyl-2-thiourea, isopropylthiourea, 1-phenyl-2-thiourea, 1,3-diethylthiourea, and diphenylthiourea are more preferable; and thiourea, N-methylthiourea, 1-allyl-3-(2-hydroxyethyl)-2-thiourea, and thiourea dioxide are very preferable for use because these are industrially easily available, and their solubilities in the alkaline solution are high as about 10,000 ppm.

It is possible to properly determine a concentration of hydroxylamine which is used in the present invention according to a desired silicon etching rate, and hydroxylamine is preferably used at a concentration of from 3 to 15% by mass. The concentration is more preferably in the range of from 5 to 15% by mass, still more preferably in the range of from 7 to 13% by mass, and especially preferably in the range of from 9 to 11% by mass. When the hydroxylamine concentration is 5% by mass or more, since a rate of lowering of the etching rate of silicon at the time of coexistence of Cu does not become low, an effect for suppressing the lowering of the etching rate of silicon of the present etching solution is distinctly obtained. In increasing the hydroxylamine concentration, following this, the etching rate tends to increase monotonously. On the other hand, when the concentration is not more than 11% by mass, an effect for enhancing the etching rate due to the concentration of hydroxylamine is efficiently obtained. The hydroxylamine concentration may be properly determined while taking into consideration a desired etching rate.

In general, the silicon etching method of the present invention adopts a method of immersing an object in a heated etching solution, taking out it after elapsing a prescribed period of time, washing away the etching solution attached to the object with water or the like, and then drying attached water. An etching temperature is preferably a temperature of 40° C. or higher and lower than a boiling point, more preferably from 50° C. to 90° C., and especially preferably from 70° C. to 90° C. When the etching temperature is 40° C. or higher, since the etching rate does not become slow, satisfactory production efficiency can be obtained. On the other hand, when the etching temperature is not higher than 90° C., since a change in the solution composition is hardly caused, it is easy to keep the etching condition constant. When the temperature of the etching solution is made high, the etching rate increases; however, an optimum treatment temperature may be properly determined while taking into consideration minimization of a change of composition of the etching solution, or the like.

An etching time can be properly selected depending upon the etching condition and the etching object.

The object of the etching treatment in the present invention is a substrate containing monocrystalline silicon and is one in which monocrystalline silicon exists in a whole region or partial region of the substrate. Incidentally, a lowering of the silicon etching rate can be suppressed in any of the case where Cu constituting a member of the substrate such as wirings is exposed on the surface of the substrate from the beginning, or the case where Cu in the inside of the substrate is exposed on the surface by etching of silicon. It does not matter whether the monocrystalline silicon is in a single-layered state or a laminated state of multilayers. Those doped with ions in a whole region or partial region of such a substrate may also be the object of the etching treatment. Also, those in which a material such as a silicon oxide film, a silicon nitride film, or a silicon organic film, or a metal film such as an aluminum film, a chromium film, or a gold film, exists on the surface of the foregoing etching object or in the inside of the object are also included in the object of the etching treatment in the present invention.

In silicon etching as described above, even in the case where Cu exists in the solution, the silicon solution of the present invention can realize a high silicon etching rate which is an advantage of a hydroxylamine-containing alkaline aqueous solution similar to the case where Cu does not exist. Therefore, the silicon etching solution of the present invention is suitably used for etching of an object in which a silicon substrate is used, and Cu is used for its constituent member.

### EXAMPLES

The present invention is hereunder described more specifically with reference to the Examples and Comparative Examples. An etching object used for the evaluation is a monocrystalline silicon (100) (hereinafter sometimes referred to simply as “silicon (100)”) wafer. The surface on one side of this silicon (100) wafer is in a state where its entire surface is covered by a protective film made of a silicon thermal oxide film; and the surface on the other side has a pattern shape in which a part of a silicon thermal oxide film is removed by dry etching, whereby the silicon surface (0.25 cm×0.25 cm) is regularly exposed. This silicon (100) wafer was immersed in a 1% hydrofluoric acid aqueous solution at 23° C. for 15 minutes just before an etching treatment and then rinsed with ultra-pure water, followed by drying. A silicon natural oxide film formed on the surface of a portion where the silicon surface in a pattern shape was exposed was removed by this treatment with a hydrofluoric acid aqueous solution, and thereafter, the following etching treatment was carried out.

### Etching Treatment Method of Monocrystalline Silicon (100) Wafer and Calculation Method of Etching Rate

40 g of each of etching solutions was charged in a container made of PTFE (polytetrafluoroethylene), this container was dipped in a water bath, and a temperature of the etching solution was increased to 80° C. After the temperature of the etching solution reached 80° C., a monocrystalline silicon (100) (1 cm×1 cm) wafer and a Cu thin section of 0.5 cm×0.5 cm (thickness of Cu: 6,000 angstroms) were simultaneously dipped in the etching solution and subjected to an immersion treatment for 30 minutes; and thereafter, the monocrystalline silicon (100) wafer was taken out, rinsed with ultra-pure water, and then dried. In the monocrystalline silicon (100) wafer which had been subjected to an etching treatment, following the etching of monocrystalline silicon, a pattern portion became in a recessed state as compared with the surroundings thereof, and a difference of elevation between the etched portion and the non-etched portion was measured, thereby determining an etching depth of the monocrystalline silicon (100) face for 30 minutes. A value obtained by dividing this etching depth by 30 was calculated as an etching rate (unit: μm/min) of the monocrystalline silicon (100) face.

### Examples 1 to 26 and Comparative Examples 1 to 8

An etching treatment with each of etching solutions shown in Table 1 was carried out, and the results are shown in Table 1. In Comparative Examples 1 to 5, 7 and 8 not containing a thiourea, the etching rate was distinctly small as compared with that in corresponding Examples 1 to 5, 25 and 26.

### Examples 27 to 43 and Comparative Examples 9 to 11

The same procedures as those in Examples 1 to 26 were followed, except that 0.5 ppm of Cu was allowed to be contained (without containing a Cu thin section) in each of etching solutions shown in Table 2, and the results are summarized in Table 2.

In Comparative Examples 9 to 11 in which a thiourea was not added, the etching rate was distinctly small due to influences of Cu as compared with that in corresponding Examples 27, 42 and 43 in which a thiourea was added. It is noted that the thiourea has a performance of suppressing a lowering of the etching rate in not only the case where a Cu thin section exists in the etching solution but the case where Cu is dissolved in the solution.

### Examples 44 to 61 and Comparative Examples 12 to 13

### Etching Treatment of Cu Thin Section and Calculation Method of Etching Rate

40 g of each of etching solutions shown in Table 3 was charged in a container made of PTFE monocrystalline silicon (polytetrafluoroethylene), this container was dipped in a water bath, and a temperature of the etching solution was increased to 80° C. After the temperature of the etching solution reached 80° C., a Cu solid film of 2 cm×2 cm whose film thickness had been previously measured by a fluorescent X-ray analyzer (thickness of Cu: 6,000 angstroms) was simultaneously dipped in the etching solution and subjected to an immersion treatment for 60 minutes; and thereafter, the Cu thin section was taken out, rinsed with ultra-pure water, and then dried. The film thickness of the Cu thin section was again measured by a fluorescent X-ray analyzer, and a difference in the film thickness before and after the treatment was determined, thereby determining an etching depth of the Cu thin section for 60 minutes. A value obtained by dividing this etching depth by 60 was calculated as an etching rate (unit: angstrom/min) of Cu. In the case of containing a thiourea in the etching solution, the etching rate of Cu is less than 1 angstrom/min, whereas in the case of not containing a thiourea, the etching rate of Cu is 10 angstroms/min or more. From these results, it was found that in the case where Cu coexists, the thiourea has not only an effect of not lowering the etching rate of Si but a performance of preventing dissolution of Cu.

### Comparative Examples 14 to 33

The same procedures as those in Example 27 were followed, except that 0.5 ppm of Cu was allowed to be contained (without containing a Cu thin section) in each of etching solutions shown in Table 4, and the results are summarized in Table 4. In view of the fact that in the silicon etching solution of the present invention, even in the case where Cu exists in the solution, a high silicon etching rate which is an advantage of a hydroxylamine-containing alkaline aqueous solution can be realized similar to the case where Cu does not exist, it may be considered that the thiourea (3) that is one of the components thereof gives rise to a performance of forming a chelate together with Cu. But, in the case of using each of chelating agents having a performance of forming a chelate together with Cu, which are used in Comparative Examples 14 to 33, it was shown that the silicon etching performance was conspicuously deteriorated as compared with the silicon etching solution of the present invention. That is, according to the present invention, it was shown that excellent effects are obtained due to a synergistic effect of the thiourea (3) with other components, i.e., the alkaline hydroxide (1) and the hydroxylamine (2).

TABLE 1

| | | Concentration | Concentration | | Concentration | |
|---|---|---|---|---|---|---|
| | Alkaline | of alkaline | of hydroxylamine | | of thiourea | Si.E.R. |
| | hydroxide | hydroxide (%) | (%) | Thiourea | (ppm) | (μm/min) |
| Example 1 | KOH | 24 | 10 | Thiourea | 1000 | 4.1 |
| Comparative | KOH | 24 | 10 | No | — | 1.9 |
| Example 1 | | | | | | |
| Exmaple 2 | KOH | 15 | 10 | Thiourea | 1000 | 3.6 |
| Comparative | KOH | 15 | 10 | No | — | 3.0 |
| Example 2 | | | | | | |
| Example 3 | KOH | 35 | 10 | Thiourea | 1000 | 4.2 |
| Comparative | KOH | 35 | 10 | No | — | 2.7 |
| Example 3 | | | | | | |
| Example 4 | KOH | 24 | 11 | Thiourea | 1000 | 4.6 |
| Comparative | KOH | 24 | 11 | No | — | 3.7 |
| Example 4 | | | | | | |
| Example 5 | KOH | 24 | 5 | Thiourea | 1000 | 2.8 |
| Comparative | KOH | 24 | 5 | No | — | 2.0 |
| Example 5 | | | | | | |
| Example 6 | KOH | 24 | 10 | Thiourea | 1 | 3.9 |
| Example 7 | KOH | 24 | 10 | Thiourea | 10 | 4.3 |
| Example 8 | KOH | 24 | 10 | Thiourea | 100 | 4.2 |
| Example 9 | KOH | 24 | 10 | Thiourea | 2000 | 4.1 |
| Example 10 | KOH | 24 | 10 | Thiourea | 5000 | 4.0 |
| Example 11 | KOH | 24 | 10 | Thiourea | 10000 | 3.7 |
| Example 12 | KOH | 24 | 10 | 1-Allyl-3-(2-hydroxyethyl)-2-thiourea | 1000 | 3.9 |
| Example 13 | KOH | 24 | 10 | 1,3-Dimethyl-2-thiourea | 1000 | 3.8 |
| Example 14 | KOH | 24 | 10 | Thiourea dioxide | 1000 | 4.0 |
| Example 15 | KOH | 24 | 10 | 1-Benzoyl-2-thiourea | 1000 | 3.9 |
| Example 16 | KOH | 24 | 10 | N-Methylthiourea | 1000 | 4.1 |
| Example 17 | KOH | 24 | 10 | Isopropylthiourea | 1000 | 4.0 |
| Example 18 | KOH | 24 | 10 | 1-Phenyl-2-thiourea | 1000 | 4.1 |
| Example 19 | KOH | 24 | 10 | 1,3-Diethyl-2-thiourea | 1000 | 3.9 |
| Example 20 | KOH | 24 | 10 | Diphenylthiourea | 100 | 3.8 |
| Example 21 | KOH | 24 | 10 | Benzylthiourea | 10 | 4.3 |
| Example 22 | KOH | 24 | 10 | N-t-Butyl-N′-isopropylthiourea | 10 | 3.9 |
| Example 23 | KOH | 24 | 10 | N,N′-Diisopropylthiourea | 10 | 4.1 |
| Example 24 | KOH | 24 | 10 | 1,3-Di-n-butylthiourea | 10 | 4.3 |
| Comparative | KOH | 24 | 10 | Urea | 1000 | 2.0 |
| Example 6 | | | | | | |
| Example 25 | NaOH | 10 | 10 | Thiourea | 1000 | 3.5 |
| Comparative | NaOH | 10 | 10 | No | — | 1.5 |
| Example 7 | | | | | | |
| Example 26 | TMAH | 11 | 10 | Thiourea | 1000 | 1.5 |
| Comparative | TMAH | 11 | 10 | No | — | 0.7 |
| Example 8 | | | | | | |

Immersion temperature: 80° C.,
Immersion time: 30 minutes
KOH: Potassium hydroxide,
NaOH: Sodium hydroxide,
TMAH: Tetramethylammonium hydroxide

TABLE 2

| | | | | | Concen- | Concen- | |
|---|---|---|---|---|---|---|---|
| | | Concentration | Concentration | | tration of | tration of | |
| | Alkaline | of alkaline | of hydrox- | | thiourea | added Cu | Si.E.R. |
| | hydroxide | hydroxide (%) | ylamine (%) | Thiourea | (ppm) | (ppm) | (μm/min) |
| Example 27 | KOH | 24 | 10 | Thiourea | 1000 | 0.5 | 4.5 |
| Example 28 | KOH | 24 | 10 | Thiourea | 1000 | 0 | 4.3 |
| Comparative | KOH | 24 | 10 | No | — | 0.5 | 1.5 |
| Example 9 | | | | | | | |
| Example 29 | KOH | 24 | 10 | 1-Allyl-3-(2-hydroxyethyl)-2-thiourea | 1000 | 0.5 | 4.4 |
| Example 30 | KOH | 24 | 10 | 1,3-Dimethyl-2-thiourea | 1000 | 0.5 | 4.5 |
| Example 31 | KOH | 24 | 10 | Thiourea dioxide | 1000 | 0.5 | 4.5 |
| Example 32 | KOH | 24 | 10 | 1-Benzoyl-2-thiourea | 1000 | 0.5 | 4.8 |
| Example 33 | KOH | 24 | 10 | N-Methylthiourea | 1000 | 0.5 | 4.7 |
| Example 34 | KOH | 24 | 10 | Isopropylthiourea | 1000 | 0.5 | 4.5 |
| Example 35 | KOH | 24 | 10 | 1-Phenyl-2-thiourea | 1000 | 0.5 | 4.6 |
| Example 36 | KOH | 24 | 10 | 1,3-Diethyl-2-thiourea | 1000 | 0.5 | 4.7 |
| Example 37 | KOH | 24 | 10 | Diphenylthiourea | 100 | 0.5 | 4.5 |
| Example 38 | KOH | 24 | 10 | Benzylthiourea | 10 | 0.5 | 4.4 |
| Example 39 | KOH | 24 | 10 | N-t-Butyl-N′-isopropylthiourea | 10 | 0.5 | 3.9 |
| Example 40 | KOH | 24 | 10 | N,N′-Diisopropylthiourea | 10 | 0.5 | 4.1 |
| Example 41 | KOH | 24 | 10 | 1,3-Di-n-butylthiourea | 10 | 0.5 | 4.3 |
| Example 42 | NaOH | 10 | 10 | Thiourea | 1000 | 0.5 | 3.5 |
| Comparative | NaOH | 10 | 10 | No | — | 0.5 | 1.5 |
| Example 10 | | | | | | | |
| Example 43 | TMAH | 11 | 10 | Thiourea | 1000 | 0.5 | 1.5 |
| Comparative | TMAH | 11 | 10 | No | — | 0.5 | 0.7 |
| Example 11 | | | | | | | |

Immersion temperature: 80° C.,
Immersion time: 30 minutes
KOH: Potassium hydroxide,
NaOH: Sodium hydroxide,
TMAH: Tetramethylammonium hydroxide

TABLE 3

| | | Concentration | Concentration | | Concentration | |
|---|---|---|---|---|---|---|
| | Alkaline | of alkaline | of hydroxylamine | | of thiourea | Si.E.R. |
| | hydroxide | hydroxide (%) | (%) | Thiourea | (ppm) | (μm/min) |
| Example 44 | KOH | 24 | 10 | Thiourea | 1 | <1 |
| Comparative | KOH | 24 | 10 | No | — | 16.0 |
| Example 12 | | | | | | |
| Example 45 | KOH | 24 | 10 | Thiourea | 10 | <1 |
| Example 46 | KOH | 24 | 10 | Thiourea | 100 | <1 |
| Example 47 | KOH | 24 | 10 | Thiourea | 1000 | <1 |
| Example 48 | KOH | 24 | 10 | 1-Allyl-3-(2-hydroxyethyl)-2-thiourea | 1000 | <1 |
| Example 49 | KOH | 24 | 10 | 1,3-Dimethyl-2-thiourea | 1000 | <1 |
| Example 50 | KOH | 24 | 10 | Thiourea dioxide | 1000 | <1 |
| Example 51 | KOH | 24 | 10 | 1-Benzoyl-2-thiourea | 1000 | <1 |
| Example 52 | KOH | 24 | 10 | N-Methylthiourea | 1000 | <1 |
| Example 53 | KOH | 24 | 10 | Isopropylthiourea | 1000 | <1 |
| Example 54 | KOH | 24 | 10 | 1-Phenyl-2-thiourea | 1000 | <1 |
| Example 55 | KOH | 24 | 10 | 1,3-Diethyl-2-thiourea | 1000 | <1 |
| Example 56 | KOH | 24 | 10 | Diphenylthiourea | 100 | <1 |
| Example 57 | KOH | 24 | 10 | Benzylthiourea | 10 | <1 |
| Example 58 | KOH | 24 | 10 | N-t-Butyl-N′-isopropylthiourea | 10 | <1 |
| Example 59 | KOH | 24 | 10 | N,N′-Diisopropylthiourea | 10 | <1 |
| Example 60 | KOH | 24 | 10 | 1,3-Di-n-butylthiourea | 10 | <1 |
| Example 61 | TMAH | 11 | 10 | Thiourea | 1000 | <1 |
| Comparative | TMAH | 11 | 10 | No | — | 15.3 |
| Example 13 | | | | | | |

Immersion temperature: 80° C.,
Immersion time: 60 minutes
KOH: Potassium hydroxide,
NaOH: Sodium hydroxide,
TMAH: Tetramethylammonium hydroxide

TABLE 4

| | | Concentration | Concentration | | Concentration | |
|---|---|---|---|---|---|---|
| | Alkaline | of alkaline | of hydroxylamine | | of thiourea | Si.E.R. |
| | hydroxide | hydroxide (%) | (%) | Thiourea | (ppm) | (μm/min) |
| Comparative | KOH | 24 | 10 | Ammonia | 1000 | 4.1 |
| Example 13 | | | | | | |
| Comparative | KOH | 24 | 10 | Ethylenediamine | 1000 | 1.9 |
| Example 14 | | | | | | |
| Comparative | KOH | 24 | 10 | β-Alanine | 1000 | 3.6 |
| Example 15 | | | | | | |
| Comparative | KOH | 24 | 10 | Glycine | 1000 | 3.0 |
| Example 16 | | | | | | |
| Comparative | KOH | 24 | 10 | Ethylenediaminetetraacetatic | 1000 | 4.2 |
| Example 17 | | | | acid (EDTA) | | |
| Comparative | KOH | 24 | 10 | 5-Amino-1H-tetrazole monohydrate | 1000 | 2.7 |
| Example 18 | | | | | | |
| Comparative | KOH | 24 | 10 | 1,2,3-Benzotriazole | 1000 | 4.6 |
| Example 19 | | | | | | |
| Comparative | KOH | 24 | 10 | Urea | 1000 | 3.7 |
| Example 20 | | | | | | |
| Comparative | KOH | 24 | 10 | Citric acid | 1000 | 2.8 |
| Example 21 | | | | | | |
| Comparative | KOH | 24 | 10 | Malic acid | 1000 | 2.0 |
| Example 22 | | | | | | |
| Comparative | KOH | 24 | 10 | Oxalic acid | 1000 | 3.9 |
| Example 23 | | | | | | |
| Comparative | KOH | 24 | 10 | Succinic acid | 1000 | 4.3 |
| Example 24 | | | | | | |
| Comparative | KOH | 24 | 10 | Diethylenetriamine | 1000 | 4.2 |
| Example 25 | | | | pentamethylenephosphonic acid (DTPP) | | |
| Comparative | KOH | 24 | 10 | 1,2-Propylenediamine | 1000 | 4.1 |
| Example 26 | | | | tetramethylenephosphonic acid (PDTP) | | |
| Comparative | KOH | 24 | 10 | Methylene diphosphonic acid | 1000 | 4.0 |
| Example 27 | | | | | | |
| Comparative | KOH | 24 | 10 | Lactic acid | 1000 | 3.7 |
| Example 28 | | | | | | |
| Comparative | KOH | 24 | 10 | Aspartic acid | 1000 | 3.9 |
| Example 29 | | | | | | |
| Comparative | KOH | 24 | 10 | Glycolic acid | 1000 | 3.8 |
| Example 30 | | | | | | |
| Comparative | KOH | 24 | 10 | Tartaric acid | 1000 | 4.0 |
| Example 31 | | | | | | |
| Comparative | KOH | 24 | 10 | Maleic acid | 1000 | 3.9 |
| Example 32 | | | | | | |
| Comparative | KOH | 24 | 10 | Iminodiacetic acid | 1000 | 4.1 |
| Example 33 | | | | | | |

Immersion temperature: 80° C.,
Immersion time: 30 minutes
KOH: Potassium hydroxide

### INDUSTRIAL APPLICABILITY

In etching of silicon containing Cu, an etching solution which does not lower an etching rate of silicon and does not etch Cu can be provided and is industrially useful.

1. A silicon etching solution, comprising an alkaline aqueous solution comprising:
(1) at least one hydroxide selected from the group consisting of potassium hydroxide, sodium hydroxide, and tetramethylammonium hydroxide;
(2) hydroxylamine; and
(3) a thiourea.

2. The silicon etching solution of claim 1, wherein the thiourea (3) is at least one selected from the group consisting of thiourea, N-methylthiourea, 1-allyl-3-(2-hydroxyethyl)-2-thiourea, thiourea dioxide, 1,3-dimethylthiourea, 1-benzoyl-2-thiourea, isopropylthiourea, 1-phenyl-2-thiourea, 1,3-diethylthiourea, diphenylthiourea, benzylthiourea, N-t-butyl-N′-isopropylthiourea, N,N′-diisopropylthiourea, and di-n-butylthiourea.

3. The silicon etching solution of claim 1, wherein the thiourea (3) is at least one selected from the group consisting of thiourea, N-methylthiourea, 1-allyl-3-(2-hydroxyethyl)-2-thiourea, thiourea dioxide, 1,3-dimethylthiourea, 1-benzoyl-2-thiourea, isopropylthiourea, 1-phenyl-2-thiourea, 1,3-diethylthiourea, and diphenylthiourea.

4. The silicon etching solution of claim 1, wherein the thiourea (3) is at least one selected from the group consisting of thiourea, N-methylthiourea, 1-allyl-3-(2-hydroxyethyl)-2-thiourea, and thiourea dioxide.

5. The silicon etching solution of claim 1, which is suitable for etching an object comprising a silicon substrate, and Cu.

6. A silicon etching method, the method comprising etching an object with an alkaline aqueous solution comprising:
(1) an alkaline hydroxide;
(2) hydroxylamine; and
(3) a thiourea.

7. The silicon etching method of claim 6, wherein:
the alkaline hydroxide (1) is at least one selected from the group consisting of potassium hydroxide, sodium hydroxide, and tetramethylammonium hydroxide; and
the thiourea (3) is at least one selected from the group consisting of thiourea, N-methylthiourea, 1-allyl-3-(2-hydroxyethyl)-2-thiourea, thiourea dioxide, 1,3-dimethylthiourea, 1-benzoyl-2-thiourea, isopropylthiourea, 1-phenyl-2-thiourea, 1,3-diethylthiourea, diphenylthiourea, benzylthiourea, N-t-butyl-N′-isopropylthiourea, N,N′-diisopropylthiourea, and di-n-butylthiourea.

8. The silicon etching method of claim 6, wherein the object comprises a silicon substrate, and Cu.

9. The solution of claim 5, wherein an etching rate of silicon in the object is not lower than an etching rate of silicon in an object not comprising Cu.

10. The silicon etching solution of claim 2, which is suitable for etching an object comprising a silicon substrate and Cu, such that an etching rate of silicon in the object is not lower than an etching rate of silicon in an object not comprising Cu.

11. The silicon etching solution of claim 3, which is suitable for etching an object comprising a silicon substrate and Cu, such that an etching rate of silicon in the object is not lower than an etching rate of silicon in an object not comprising Cu.

12. The silicon etching solution of claim 4, which is suitable for etching an object comprising a silicon substrate and Cu, such that an etching rate of silicon in the object is not lower than an etching rate of silicon in an object not comprising Cu.

13. The silicon etching solution of claim 9, wherein the solution is suitable for dissolving monocrystalline silicon anisotropically.

14. The method of claim 7, wherein the object comprises a silicon substrate and Cu.

15. The method of claim 8, wherein an etching rate of silicon in the object is not lower than an etching rate of silicon in an object not comprising Cu.

16. The method of claim 14, wherein an etching rate of silicon in the object is not lower than an etching rate of silicon in an object not comprising Cu.

17. The solution of claim 5, wherein an etching rate of silicon in the object is higher than an etching rate of silicon in an object not comprising Cu.

18. The method of claim 8, wherein an etching rate of silicon in the object is higher than an etching rate of silicon in an object not comprising Cu.

19. The method of claim 6, which is suitable for dissolving monocrystalline silicon anisotropically.

20. The method of claim 14, wherein an etching rate of silicon in the object is higher than an etching rate of silicon in an object not comprising Cu.
